(19) United States
(12) Patent Application Publication
(10) Pub. No.: US 2009/0108473 A1
(43) Pub. Date: Apr. 30, 2009

(54) DIE-ATTACH MATERIAL OVERFLOW CONTROL FOR DIE PROTECTION IN INTEGRATED CIRCUIT PACKAGES

(75) Inventors: Ken Jian Ming Wang, Irvine, CA (US); Muh-Ren Lin, Irvine, CA (US); Rezaur Rahman Khan, Rancho Santa Margarita, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 11/925,086

(22) Filed: Oct. 26, 2007

(51) Int. Cl. H01L 23/49; H01L 21/58

(52) U.S. Cl. 257/783; 438/118; 257/E23.024; 257/E21.505; 257/678

(57) ABSTRACT

Methods, systems, and apparatuses for integrated circuit packages are provided. An integrated circuit package includes a metal layer, an integrated circuit die, and an adhesive material. The metal layer has a first surface that has a die-attach region. The metal layer further has one or more recessed regions formed in the first surface of the metal layer adjacent to the die-attach region. The adhesive material attaches a first surface of the die to the die-attach region and at least partially fills the recessed region(s). Excess adhesive material flows into the recessed region(s) during application of the die to the die-attach region, so that the side surfaces of the die remain substantially uncovered by the adhesive material. By preventing the excess adhesive material from covering the side surfaces of the die, the adhesive material is prevented from penetrating the side surfaces of the die, which could damage the die.

### BACKGROUND OF THE INVENTION

1. Field of the Invention

The present invention relates to integrated circuit packaging technology and more particularly to attachment of integrated circuit dies to substrates.

2. Background Art

Integrated circuit (IC) chips or dies from semiconductor wafers are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

In many types of IC packages, including some BGA packages, a die is attached to a substrate of the package, such as a circuit board substrate or metal layer, using an adhesive material. For example, the adhesive material may be applied to a surface of the substrate in a die-attach region. The die is subsequently positioned in the die attach region on the adhesive material, causing excess adhesive material to flow out from between the die and substrate. Due to surface tension and/or other effects, the excess adhesive material may creep up the sides of the die, partially or entirely covering the sides of the die. The excess adhesive material may penetrate the sides of the die, such as at regions of the sides of the die where micro-cracks are present that were formed during a process of singulating the die from a wafer. Curing of the adhesive material may cause the adhesive material that penetrated the die to expand, causing damage to the die, which may cause the die to become inoperative.

Millions of integrated circuit packages are needed each year to be implemented in electronic devices. What are needed are improved packaging techniques that can help meet the high quantity production needs for integrated circuit packages, while avoiding damage to the dies caused by excess adhesive material.

### BRIEF SUMMARY OF THE INVENTION

Methods, systems, and apparatuses for integrated circuit packages, and processes for assembling the same, are provided. Recessed regions are formed adjacent to die mounting locations in an integrated circuit package. The recessed regions receive excess die-attach adhesive material when the die is placed in the die mounting location, preventing the excess adhesive material from substantially covering one or more sides of the die. By preventing the excess adhesive material from covering side surfaces of the die, the adhesive material is prevented from penetrating the side surfaces of the die, which could otherwise damage the die.

In a first example aspect, an integrated circuit package includes a metal layer, an integrated circuit die, and an adhesive material. The metal layer has a first surface that has a die-attach region. The metal layer further has one or more recessed regions formed in the first surface of the metal layer adjacent to the die-attach region. The adhesive material attaches a first surface of the die to the die-attach region and at least partially fills the recessed region(s). Excess adhesive material flows into the recessed region(s) during application of the die to the die-attach region, so that the side surfaces of the die remain substantially uncovered by the adhesive material.

The integrated circuit package may be any type of integrated circuit package, including a die-up or die-down ball grid array package.

In another example aspect, an integrated circuit package is assembled. An adhesive material is applied to a die-attach region of a first surface of a metal layer. An integrated circuit die is applied to the adhesive material, thereby causing a portion of the adhesive material to flow from between the die and first surface of the metal layer into a recessed region in the first surface of the metal layer such that a plurality of side surfaces of the die remain substantially uncovered by the adhesive material. The adhesive material is cured to attach the die to the die-attach region.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a cross-sectional side view of an example BGA package.

FIG. 2 shows a bottom view of the BGA package of FIG. 1.

FIGS. 3 and 4 show cross-sectional side and top views, respectively, of an example die-up BGA package having a metal layer

FIGS. 5 and 6 show cross-sectional side and bottom views, respectively, of an example die-down BGA package.

FIGS. 7 and 8 show cross-sectional side views of a portion of an integrated circuit package.

FIG. 9 shows a cross-sectional side view of a portion of an integrated circuit package, according to an example embodiment of the present invention.

FIG. 10 shows a flowchart providing a process for assembling an integrated circuit (IC) package, according to embodiments of the present invention.

FIG. 11 shows an additional step that may be performed in the flowchart of FIG. 10, according to an example embodiment of the present invention.

FIG. 12 shows a cross-sectional side view of a portion of an integrated circuit package, according to an example embodiment of the present invention.

FIG. 13 shows a plan view of a metal layer, according to an example embodiment of the present invention.

FIG. 14 shows an example pattern of adhesive material used to mount a die, with surrounding recessed regions for receiving excess adhesive material, according to an embodiment of the present invention.

FIG. 15 shows additional assembly steps for the flowchart of FIG. 10 to form a die-up integrated circuit package, according to an embodiment of the present invention.

FIG. 16 shows a cross-sectional side view of an example die-up BGA package, according to an embodiment of the present invention.

FIG. 17 shows additional assembly steps for the flowchart of FIG. 10 to form a die-down integrated circuit package, according to an embodiment of the present invention.

FIG. 18 shows a cross-sectional side view of an example die-down BGA package, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Integrated Circuit Packages

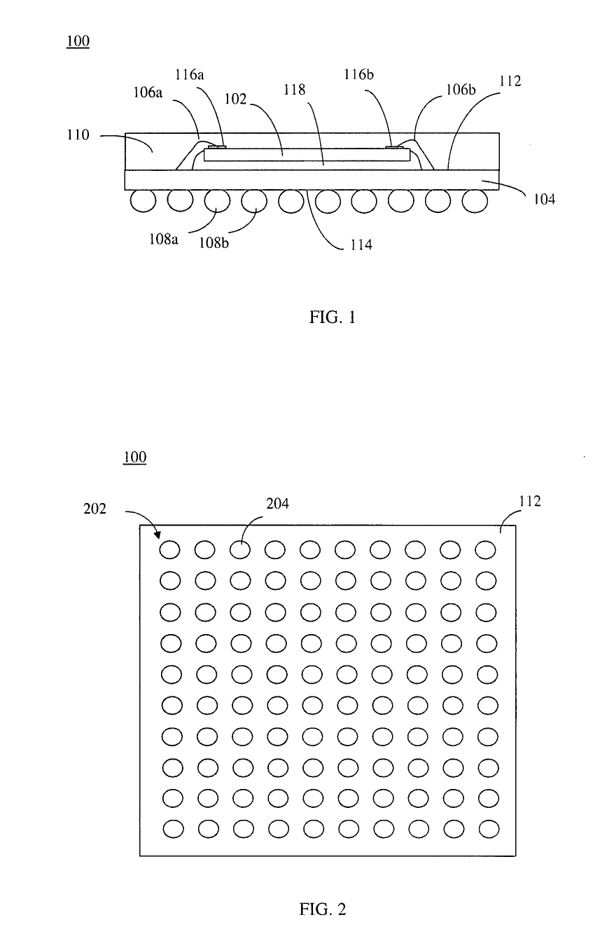

Embodiments of the present invention are applicable to a variety of types of integrated circuit packages, including ball grid array (BGA) packages. FIG. 1 shows a cross-sectional view of an example BGA package 100. BGA package 100 may be a plastic BGA (PBGA) package, a flex BGA package, a ceramic BGA package, a fine pitch BGA (FPBGA or FBGA) package, or other type of BGA package. BGA package 100 includes an integrated circuit die/chip 102, a substrate 104, bond wires (also known as “wire bonds”) 106, a plurality of solder balls 108, and an encapsulating material 110. Substrate 104 has a first (e.g., top) surface 112 that is opposed to a second (e.g., bottom) surface 114 of substrate 104. As shown in FIG. 1, die 102 is mounted to first surface 112 of substrate 104. Die 102 may be mounted to substrate 104 using an adhesive material 118.

As shown in FIG. 1, a plurality of bond wires 106 are coupled between terminals 116 of die 102 and electrically conductive features, such as traces, bond fingers, etc. (not shown in FIG. 1), at first surface 112 of substrate 104. For example, a first bond wire 106a is connected between a terminal 116a and first surface 112 of substrate 104, and a second bond wire 106b is connected between a terminal 116b and first surface 112 of substrate 104. Any number of bond wires 106 may be present, depending on a number of signals (at terminals 116) of die 102 to be coupled to conductive features of first surface 112 of substrate 104. Bond wires 106 may be wires formed of any suitable electrically conductive material, including a metal such as gold, silver, copper, aluminum, other metal, or combination of metals/alloy. Bond wires 106 may be attached according to wire bonding techniques and mechanisms well known to persons skilled in the relevant art(s).

As further shown in FIG. 1, encapsulating material 110 covers die 102 and bond wires 106 on first surface 112 of substrate 104. Encapsulating material 110 protects die 102 and bond wires 106 from environmental hazards. Encapsulating material 110 may be any suitable type of encapsulating material, including an epoxy, a mold compound, etc. Encapsulating material 110 may be applied in a variety of ways, including by a saw singulation technique, injection into a mold, etc.

A plurality of solder balls 108 (including solder balls 108a and 108b indicated in FIG. 1) is attached to second surface 114 of substrate 104. FIG. 2 shows a plan (bottom) view of second surface 114 of substrate 104. Solder balls 108 are not shown in FIG. 2. Instead, in FIG. 2, second surface 114 of substrate 104 includes an array 202 of solder balls pads 204. In the example of FIG. 2, array 202 includes one hundred solder ball pads 204 arranged in a 10 by 10 array. In other implementations, array 202 may include fewer or greater numbers of solder ball pads 204 arranged in any number of rows and columns. Solder ball pads 204 are attachment locations for solder balls 108 (shown in FIG. 1) on package 100. Solder ball pads 204 are electrically coupled through substrate 104 (e.g., by electrically conductive vias and/or routing) to the electrically conductive features (e.g., traces, bond fingers, contact regions, etc.) of first surface 112 of substrate 104 to enable signals of die 102 to be electrically connected to solder balls 108. Note that FIG. 2 shows a full array of solder ball pads 204. In some embodiments, array 202 of solder ball pads 204 may be missing some pads 204, so that array 202 is not necessarily a full array of solder balls 108 on second surface 114.

Substrate 104 may include one or more electrically conductive layers (such as at first surface 112) that are separated by one or more electrically insulating layers. An electrically conductive layers may include traces/routing, bond fingers, contact pads, and/or other electrically conductive features. For example, BGA substrates having one electrically conductive layer, two electrically conductive layers, or four electrically conductive layers are common. The electrically conductive layers may be made from an electrically conductive material, such as a metal or combination of metals/alloy, including copper, aluminum, tin, nickel, gold, silver, etc. In embodiments, substrate 104 may be rigid or may be flexible (e.g., a “flex” substrate). The electrically insulating layer(s) may be made from ceramic, plastic, tape, and/or other suitable materials. For example, the electrically insulating layer(s) of substrate 104 may be made from an organic material such as BT (bismaleimide triazine) laminate/resin, a flexible tape material such as polyimide, a flame retardant fiberglass composite substrate board material (e.g., FR-4), etc.

Other configurations for BGA package 100 are within the scope of embodiments of the present invention. For example, package 100 in FIG. 1 is a die-up type BGA package. Alternatively, package 100 may be configured as a die-down BGA package, where die 102 is mounted to a bottom surface of package 100. Furthermore, package 100 may include heat spreaders and/or heat sinks configured to spread heat within and/or outside package 100.

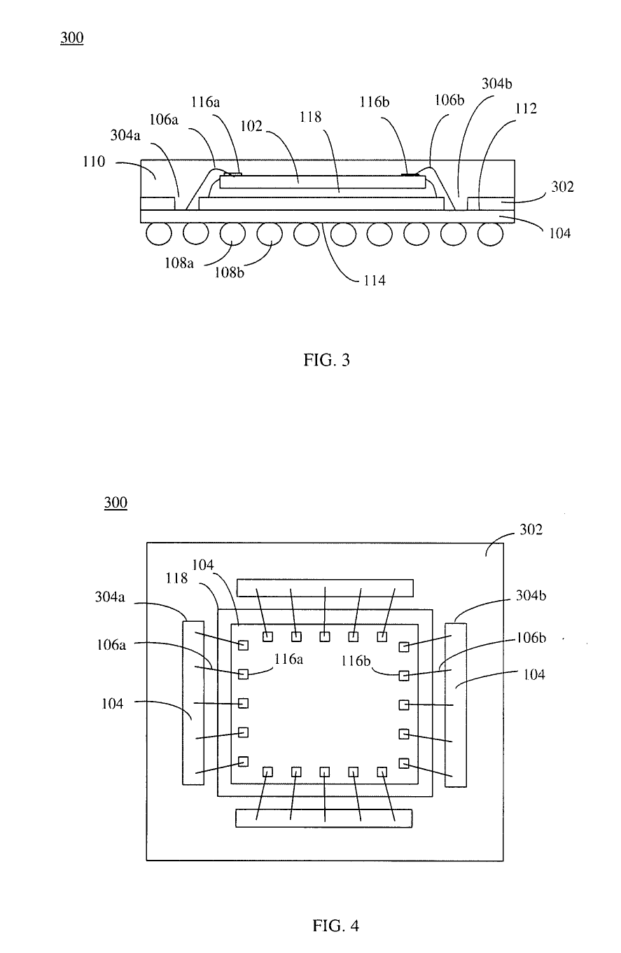

For example, FIGS. 3 and 4 show cross-sectional side and plan views, respectively, of a BGA package 300 that is generally similar to BGA package 100 of FIG. 1, with the addition of a metal layer 302. Die 102 is mounted to a top surface of metal layer 302, and metal layer 302 is attached to first surface 112 of first substrate 302. Metal layer 302 may be present in package 300 to stiffen package 300 and/or to provide heat spreading for package 300. For example, heat generated by die 102 during operation can be transferred from die 102 to metal layer 302. Metal layer 302 may also be referred to as a heat spreader and/or stiffener in some implementations. Metal layer 302 may be made from a thermally conductive material, such as being a solid piece of metal (e.g., copper, aluminum, etc.) or combination of metals/alloy. Metal layer 302 may include a plurality of openings 304 (e.g., openings 304a and 304b shown in FIG. 3) through metal layer 302.

As shown in FIGS. 3 and 4, bond wires 106 are connected between terminals 116 of die 102 and first surface 112 of substrate 104 through openings 304. For example, bond wire 106a is connected between terminal 116a of die 102 and first surface 112 of substrate 104 through an opening 304a. Bond wire 106b is connected between terminal 116b of die 102 and first surface 112 of substrate 104 through an opening 304b. Any number of openings 304 may be present through metal layer 302 to accommodate bond wires 106 (and/or for other reasons).

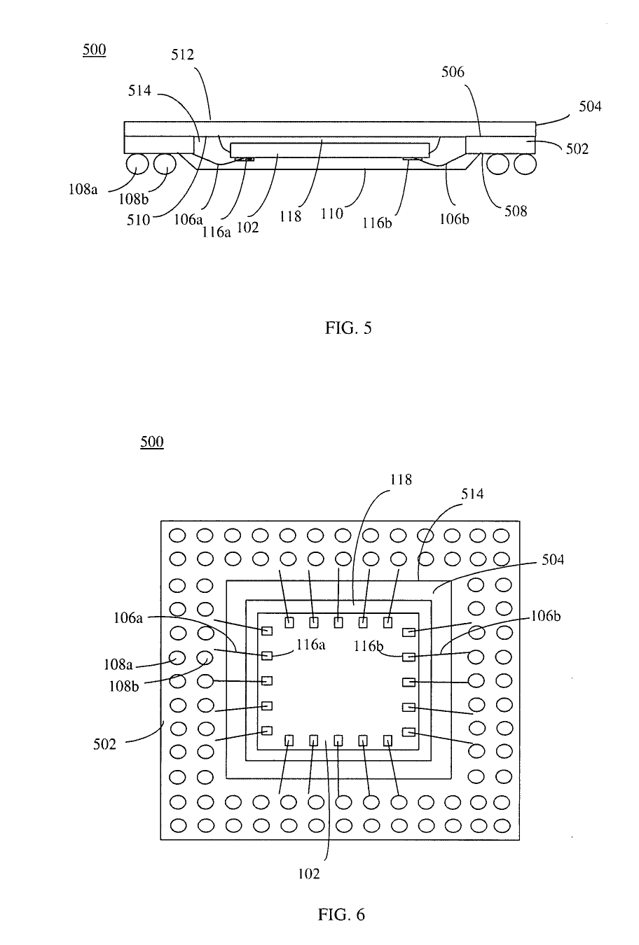

FIGS. 5 and 6 show cross-sectional side and plan views, respectively, of a BGA package 500 that is a die-down/cavity-down package configuration. Package 500 includes die 102, a substrate 502, a metal layer 504, bond wires 106, solder balls 108, and encapsulating material 110. Substrate 502 has a first (e.g., top) surface 506 that is opposed to a second (e.g., bottom) surface 508 of substrate 502. Substrate 502 has a plurality of electrically conductive features (e.g., routing, traces, contact pads, bond fingers, etc., not shown in FIGS. 5 and 6) on second surface 508 of substrate 502 that are electrically connected to a plurality of solder ball pads (not shown in FIGS. 5 and 6) on second surface 508 of substrate 502. As shown in FIGS. 5 and 6, solder balls 108 are attached to the solder ball pads on second surface 508 of substrate 502.

As shown in FIG. 5, metal layer 504 has a first (e.g., bottom) surface 510 that is opposed to a second (e.g., top) surface 512 of metal layer 504. Die 102 is mounted to first surface 510 of metal layer 504, and resides within a central opening 514 through substrate 502. Die 102 is mounted to metal layer 504 using adhesive material 118. Encapsulating material 110 covers die 102 and bond wires 106 on first surface 510 of metal layer 504.

Similarly to the description provided above for metal layer 302 shown in FIGS. 3 and 4, metal layer 504 may be present in package 500 to stiffen package 500 and/or to provide heat spreading for package 500. For example, heat generated by die 102 during operation can be transferred from die 102 to metal layer 504. Metal layer 504 may also be referred to as a heat spreader and/or stiffener in some implementations. Metal layer 504 may be made from a thermally conductive material, such as being a solid piece of metal (e.g., copper, aluminum, etc.) or combination of metals/alloy. Metal layer 504 may be formed as a core layer for substrate 502, which may be formed in a “build up” fashion on metal layer 504, or substrate 502 may be formed separately from layer 504 prior to attachment with layer 504.

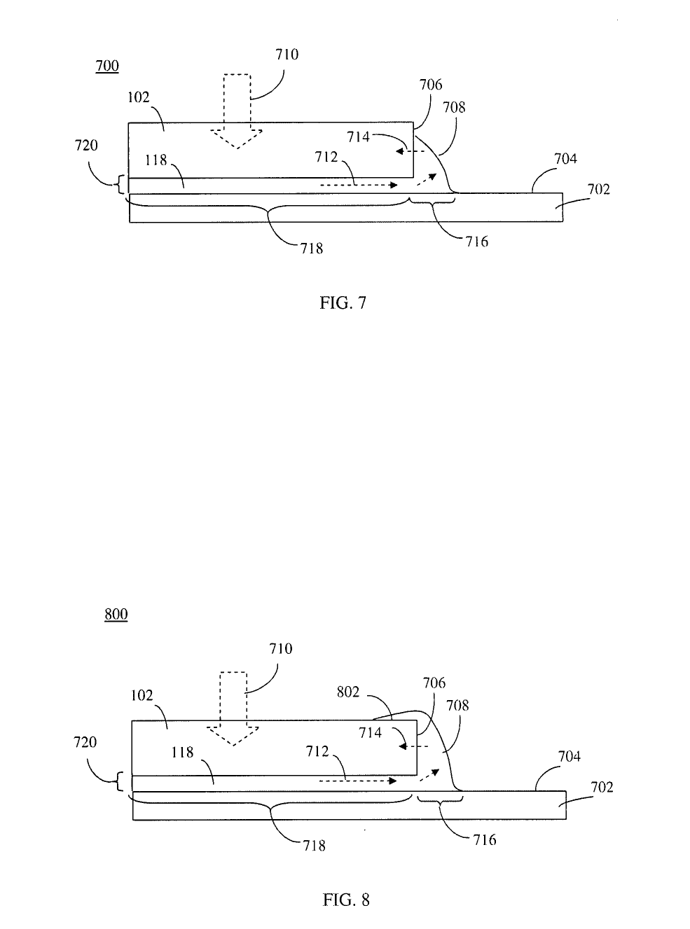

Problems exist in attaching dies to surfaces in integrated circuit packages. For example, FIGS. 7 and 8 show cross-sectional views of a portion of an integrated circuit package 700. As shown in FIGS. 7 and 8, die 102 is attached to a surface 704 of an integrated circuit package layer 702. For example, layer 702 may be metal layer 302 of package 300 shown in FIG. 3, or metal layer 504 of package 500 shown in FIG. 5. A portion of die 102 and layer 702 are shown in FIGS. 7 and 8, for ease of illustration.

As shown in FIG. 7, adhesive material 118 has been applied to surface 704 of layer 702 in a die-attach region 718. Adhesive material 118 may alternatively or additionally be applied to a surface of die 102 prior to positioning die 102 on surface 704. Die 102 is subsequently positioned in die attach region 718 on adhesive material 118 (as indicated by dotted arrow 710 in FIG. 7), causing excess adhesive material 118 to flow out from between die 102 and layer 702 (as indicated by dotted arrow 712 in FIG. 7). A bond line thickness 720 is shown in FIG. 7, which is a distance between a bottom surface of die 102 and first surface 704 of layer 702. Depending on how closely/precisely a die placement apparatus positions die 102 in die attach region 718, a corresponding amount of excess adhesive material 118 will flow from between die 102 and layer 702. From die placement to die placement operation, bond line thickness 720 may vary, resulting in different amounts of excess adhesive material 118 flowing outward.

Due to surface tension and/or other effects, the excess adhesive material 118 may creep up and collect on layer 702 at sides of die 102, such as a side 706 shown in FIG. 7, partially or entirely covering the sides of die 102. In the example of FIG. 7, an excess portion 708 of adhesive material 118 substantially covers side 706 of die 102. In the example of FIG. 8, excess portion 708 of adhesive material 118 completely covers side 706 of die 102, and a portion 802 of a top surface of die 102.

Excess portion 708 of adhesive material 118 may penetrate side 706 of die 102, causing damage to die 102. When die 102 is singulated from a wafer, die 102 may be separated from the wafer by sawing or other technique. Such techniques for cutting die 102 from a wafer may cause micro-cracks in side 706 of die 102. Die 102 may also have one or more protective layers (not shown in FIG. 7) formed on the top surface of die 102, such as a layer of polyimide, silver nitride, or other material. When excess portion 708 of adhesive material 118 comes into contact with side 706 of die 102, some of excess portion 708 may penetrate/migrate into side 706 (as indicated by dotted arrow 714 in FIGS. 7 and 8), entering the micro-cracks in die 712. Some of excess portion 708 may also penetrate/migrate between the protective layer formed on the top surface of die 102 and a next layer of die 102. Curing of adhesive material 118 may cause adhesive material 118 to expand, including causing the excess portion that penetrated die 102 to expand. Adhesive material 118 may have a higher coefficient of thermal expansion than die 102. This expansion may cause the top protective layer of die 102 to become delaminated and/or may cause the cracks in die 102 to become further opened, causing damage to die 102. If damage occurs to active areas of die 102, die 102 may cease to function properly.

Embodiments of the present invention overcome the problem of excess adhesive material causing damage to dies, without substantially increasing package cost or substantially increasing assembly process complexity. Example embodiments are further described in the following section.

### EXAMPLE EMBODIMENTS

The example embodiments described herein are provided for illustrative purposes, and are not limiting. Although described with reference to BGA packages, the examples described herein may be adapted to various types of integrated circuit packages, including leadframe based packages, such as, but not limited to, QFNs (quad flat package no leads), QFPs (quad flat packages), SSOPs (shrink small-outline packages), and further types of integrated circuit packages. Furthermore, additional structural and operational embodiments, including modifications/alterations, will become apparent to persons skilled in the relevant art(s) from the teachings herein.

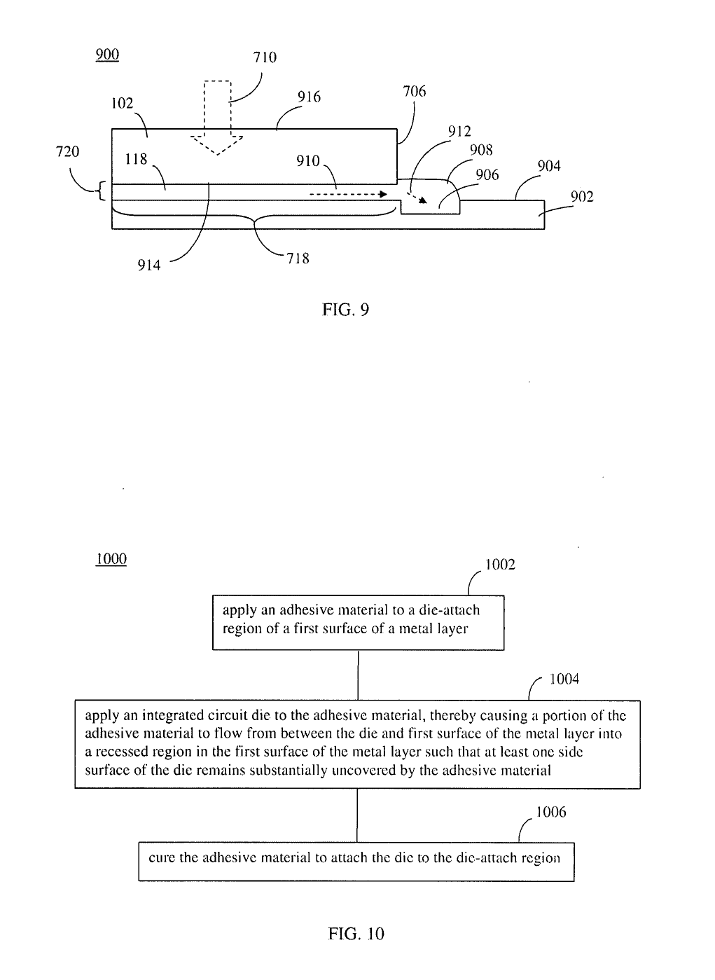

FIG. 9 shows a cross-sectional side view of a portion of an integrated circuit package 900, according to an example embodiment of the present invention. As shown in FIG. 9, package 900 includes a metal layer 902, die 102, and adhesive material 118. For example, layer 902 may be used to replace metal layer 302 of package 300 shown in FIG. 3, or metal layer 504 of package 500 shown in FIG. 5. Metal layer 902 is similar to metal layers 302 and 504, with differences described as follows. A portion of die 102 and layer 902 are shown in FIG. 9, for ease of illustration.

As shown in FIG. 9, metal layer 902 has a first surface 904 that includes die-attach region 718. Metal layer 902 further has a recessed region 906 formed in first surface 904 adjacent to die-attach region 718. Adhesive material 118 attaches a first surface 914 of die 102 to die-attach region 718 of substrate 902. An excess portion 908 of adhesive material 118 fills recessed region 906 in metal layer 902. Depending on the particular embodiment of recessed region 906, an amount of adhesive material 118 present, and/or a height of bond line thickness 720, adhesive material 118 may partially or entirely fill recessed region 906. As shown in FIG. 9, side 706 die 102 is substantially uncovered by adhesive material 118 due to recessed region 906. Adhesive material 118 is not substantially present on side 706 of die 102, and thus does not penetrate die 102, avoiding damage to die 102. For example, in an embodiment, it may be desirable to keep excess adhesive material 118 from covering more than one-half of the height of side 706 of die 102, to protect die 102 from damage. By keeping excess adhesive material 118 from flowing up more than one-half of the height of side 706 of die 102, damage to active areas of die 102 is more likely to be avoided.

FIG. 10 shows a flowchart 1000 providing a process for assembling an integrated circuit (IC) package, according to embodiments of the present invention. For instance, integrated circuit package 900 of FIG. 9 may be assembled according to flowchart 1000, to protect die 102 from excess adhesive material 118. Other structural and operational embodiments will be apparent to persons skilled in the relevant art(s) based on the discussion regarding flowchart 1000. Flowchart 1000 is described as follows.

Flowchart 1000 begins with step 1002. In step 1002, an adhesive material is applied to a die-attach region of a first surface of a metal layer. For example, as shown in FIG. 9, adhesive material 118 is applied to surface 904 of layer 902 in die-attach region 718. Adhesive material 118 may alternatively or additionally be applied to surface 914 of die 102 prior to positioning die 102 on surface 904. Adhesive material 118 may be any suitable type of adhesive, such as an epoxy, resin, or other adhesive that is applied in liquid or gel form. In an embodiment, adhesive material 118 may be an epoxy that includes metal particles (e.g., silver) used to enhance heat conduction.

In step 1004, an integrated circuit die is applied to the adhesive material, thereby causing a portion of the adhesive material to flow from between the die and first surface of the package layer into a recessed region in the first surface of the package layer such that at least one side surface of the die remains substantially uncovered by the adhesive material. For example, as shown in FIG. 9, die 102 is applied to layer 902 (as indicated by dotted arrow 710 in FIG. 9) to be positioned in die attach region 718 on adhesive material 118, causing adhesive material 118 to flow out from between die 102 and layer 702 (as indicated by dotted arrow 712 in FIG. 7). Excess portion 908 of adhesive material 118 at least partially fills recessed region 906 in surface 904 of layer 902. By receiving excess portion 908 of adhesive material 118, recessed region 906 enables side 706 to remain substantially uncovered by adhesive material 118.

In step 1006, the adhesive material is cured to attach the die to the die-attach region. Adhesive material 118 is cured to harden adhesive material 118, to cause die 102 to be attached to die-attach region 718. Adhesive material 118 may be cured in any suitable manner, including by application of heat, radiation, a curing material, etc.

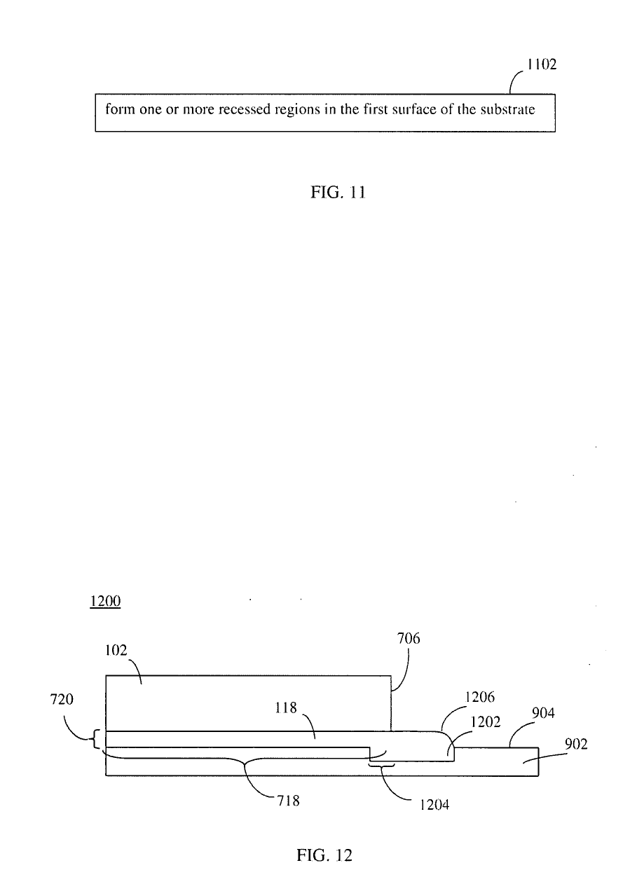

In an embodiment, flowchart 1000 may include step 1102 shown in FIG. 11. In step 1102, one or more recessed regions are formed in the first surface of the substrate. For example, step 1102 may be performed prior to step 1002 of flowchart 1000. Recessed region 906 may be formed individually, or in parallel with further recessed regions, during step 1102. Recessed region 906 may be formed in metal layer 902 in a variety of manners. For example, recessed region 906 may be formed in a planar piece of base metal plate of metal layer 902 by etching, routing, drilling, stamping, etc. Alternatively, recessed region 906 may be formed by a mold used to form metal layer 902. Recessed region 906 may be formed to have any depth in metal layer 902. For example, recessed region 906 may have a depth that is less than or equal to (≦) a half of a thickness of metal layer 902. Alternatively, in another embodiment, recessed region 906 may have a depth that is greater than a half of a thickness of metal layer 902.

Metal layer 902 may be a metal or combination of metals/alloy. For example, metal layer 902 may include a metal such as copper, aluminum, tin, nickel, gold, silver, etc. In an embodiment, metal layer 902 is a solid plate of a metal/alloy. In alternative embodiments, metal layer 902 can be made of a material other than a metal, such as a ceramic material, a glass material, or other suitable material that provides rigidity, thermal conductivity, electrical conductivity, and/or other attribute(s) desired for inclusion in an integrated circuit package.

In the embodiment of FIG. 9, recessed region 906 is formed in a portion of first surface 904 of metal layer 902 that is outside of die-attach region 718. In another embodiments, recessed region 906 may be formed overlapping die-attach region 718, or entirely within die-attach region 718. For example, FIG. 12 shows a cross-sectional view of a portion of an integrated circuit package 1200, according to an example embodiment of the present invention. Package 1200 is generally similar to package 900 shown in FIG. 9, with differences described as follows. As shown in FIG. 9, package 1200 includes metal layer 902 having a recessed region 1202 formed in first surface 904 adjacent to die-attach region 718. In FIG. 12, recessed region 1202 overlaps die-attach region 718, such that a portion 1204 of recessed region 1202 is within die-attach region 718. Thus, portion 1204 of recessed region 1202 is underneath die 102 when die 102 is mounted to die-attach region 718. An excess portion 1206 of adhesive material 118 flows into recessed region 1202 in metal layer 902. Adhesive material 118 may partially or entirely fill recessed region 1202, including portion 1204 of recessed region 1202. Side 706 die 102 remains substantially uncovered by adhesive material 118 due to recessed region 1202.

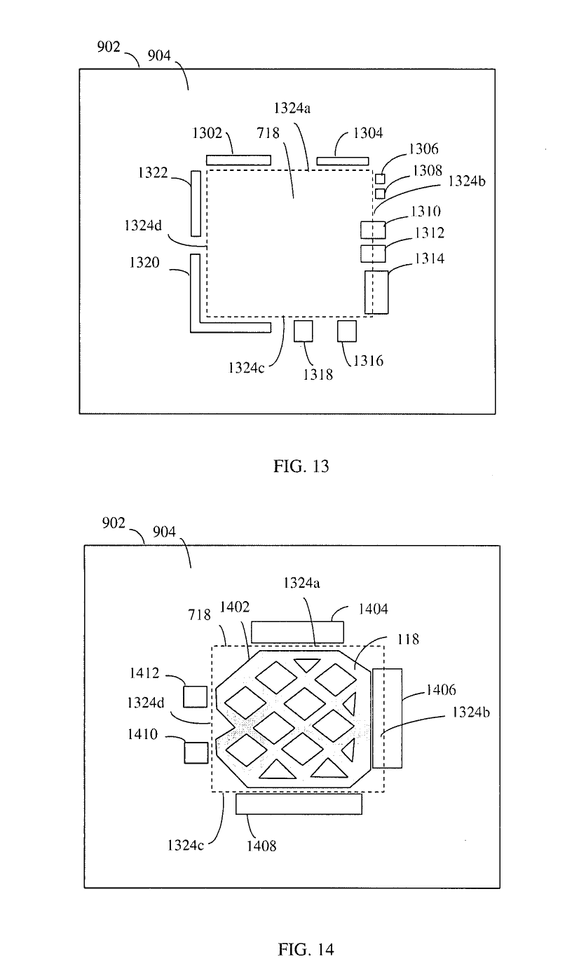

Recessed regions, such as recessed regions 906 and 1202, may be formed in any number in metal layer 902 around die-attach region 718, and in any shape. For example, FIG. 13 shows a plan view of metal layer 902, according to an example embodiment of the present invention. As shown in FIG. 13, metal layer 902 has a plurality of example recessed regions formed in first surface 904, including first-eleventh recessed regions 1302-1322. Excess portions of adhesive material 118 may flow into first-eleventh recessed regions 1302-1322 when die 102 is applied to die-attach region 718, to prevent adhesive material 118 from creeping up the sides of die 102. As shown in FIG. 13, first-eleventh recessed regions 1302-1322 have a variety of sizes and shapes.

For example, first recessed region 1302 has an elongated rectangular shape, which may also be referred to a trench shape. First recessed region 1302 extends along approximately two-fifths of a length of a first edge 1324a of die-attach region 718 from a first corner of die-attach region 718. Relative to other recessed regions in FIG. 13, first recessed region 1302 is long and narrow.

Similarly to first recessed region 1302, second recessed region 1304 has an elongated rectangular shape, and extends along approximately one-third of the length of first edge 1324a of die-attach region 718 from a second corner of die-attach region 718. Second recessed region 1304 has a width approximately the same as the width of first recessed region 1302.

Third and fourth recessed regions 1306 and 1308 are substantially square shaped, and are located next to each other, adjacent to the second corner of die-attach region 718 on a second edge 1324a of die-attach region 718. Each of recessed regions 1306 and 1308 extend along approximately one-twelfth of a length of second edge 1324a. Edges of third and fourth recessed regions 1306 and 1308 are approximately equal in length to the width of first recessed region 1302.

Fifth and sixth recessed regions 1310 and 1312 are rectangular shaped, and are located next to each other, approximately at a mid-point of second edge 1324a of die-attach region 718. In contrast to first-fourth recessed regions 1302-1308, recessed regions 1310 and 1312 each overlap die-attach region 718. Fifth and sixth recessed regions 1310 and 1312 each have lengths that extend along approximately one-eighth of a length of second edge 1324b of die-attach region 718, and have widths that are slightly greater than their lengths.

Seventh recessed region 1314 has an elongated rectangular shape, although its length is shorter, and its width is greater than the comparable dimensions of first recessed region 1302. Seventh recessed region 1302 extends along approximately one-third of a length of second edge 1324b of die-attach region 718, from a third corner of die-attach region 718.

Eighth and ninth recessed regions 1316 and 1318 are rectangular shaped, and are similar in shape and size to fifth and sixth recessed regions 1310 and 1312. However, in contrast to fifth and sixth recessed regions 1310 and 1312, recessed regions 1316 and 1318 do not overlap die-attach region 718. Eighth and ninth recessed regions 1316 and 1318 are located near the third corner of die-attach region 718 on a third edge 1324c of die-attach region 718. Each of eighth and ninth recessed regions 1316 and 1318 has a length that extends along approximately one-eighth of a length of third edge 1324c, and has a width that is slightly greater than its length.

Tenth recessed region 1320 has an elongated rectangular “L” shape, extending along approximately one-third of the lengths of both of third edge 1324c and a fourth edge 1324d of die-attach region 718, bending around a fourth corner of die-attach region 718. Second recessed region 1304 has a width approximately the same as the width of first recessed region 1302.

Similarly to first recessed region 1302, eleventh recessed region 1322 has an elongated rectangular shape, and extends along approximately one-third of the length of fourth edge 1324d of die-attach region 718, from the first corner of die-attach region 718. Eleventh recessed region 1322 has a width approximately the same as the width of first recessed region 1302.

First-eleventh recessed regions 1302-1322 are shown in FIG. 13 for illustrative purposes. Recessed regions having shapes and/or sizes different from those shown in FIG. 13 are also encompassed by embodiments of the present invention. For instance, although shown as having square/rectangular shapes in FIG. 13, recessed regions may have other shapes, including rounded (e.g., circular, oval, elliptical, etc.), triangular, hexagonal, any other polygon, irregular shape, or other shape, for example. Furthermore, recessed regions in different numbers and arrangements than shown in FIG. 13 are also encompassed by embodiments of the present invention.

For example, in an embodiment, one or more recessed regions may be configured on layer 902 according to an expected pattern of outflow of adhesive material 118 from under die 102. For example, any number of recessed regions having selected depths, selected areas, and/or positioned at any arrangement of locations of metal layer 902 may be used to accommodate an expected flow of adhesive material 118.

For instance, FIG. 14 shows an example pattern 1402 of adhesive material 118, according to an embodiment of the present invention. Pattern 1402 is a crisscrossing-type pattern of adhesive material 118 that may be formed by an applicator for adhesive material 118. As shown in FIG. 14, first-fifth recessed regions 1404-1412 are formed in layer 902 in locations of first surface 904 adjacent to die-attach region 718 where excess adhesive material 118 is expect to flow during application of die 102 to die attach region 718.

For example, first recessed region 1404 has an elongated rectangular shape. First recessed region 1404 is located along first edge 1324a of die attach region 718, parallel and adjacent to a length of adhesive material 118. Likewise, second and third recessed regions 1406 and 1408 have elongated rectangular shapes, and are respectively located along second and third edges 1324b and 1324c of die attach region 718, parallel and adjacent to respective parallel lengths of adhesive material 118. Second recessed region 1406 overlaps second edge 1324b of die-attach region 718. Fourth and fifth recessed regions 1410 and 1412 have rectangular shapes, and are both located along fourth edge 1324d of die attach region 718, adjacent to respective points of adhesive material 118. First-fifth recessed regions 1404-1412 are configured to receive excess adhesive material 118 flowing from their respective adjacent locations of die-attach region 718 during application of a die to die-attach region 718. In this manner, excess adhesive material 118 is prevented from covering any of the four edges of the die placed in die attach region 718, to avoid damage to the die.

Any pattern of adhesive material 118 may be created by an applicator, as would be known to persons skilled in the relevant art(s), such as a crisscrossing pattern as shown in FIG. 14. Example such patterns include a star pattern, a circular pattern, a square pattern, etc. Recessed regions may be arranged in metal layer 902 in any manner to accommodate an expected pattern outflow of adhesive material 118 from under die 102 during application of die 102 to layer 902, as would be understood by persons skilled in the relevant art(s) from the teachings herein.

Embodiments of metal layer 902 with recessed regions may be incorporated in a variety of types of integrated circuit packages. For example, metal layer 902 with recessed regions may be incorporated in ball grid array packages, including die-up ball grid array packages (e.g., package 100 shown in FIGS. 1 and 2, and package 300 shown in FIGS. 3 and 4) and die-down ball grid array packages (e.g., package 500 shown in FIGS. 5 and 6).

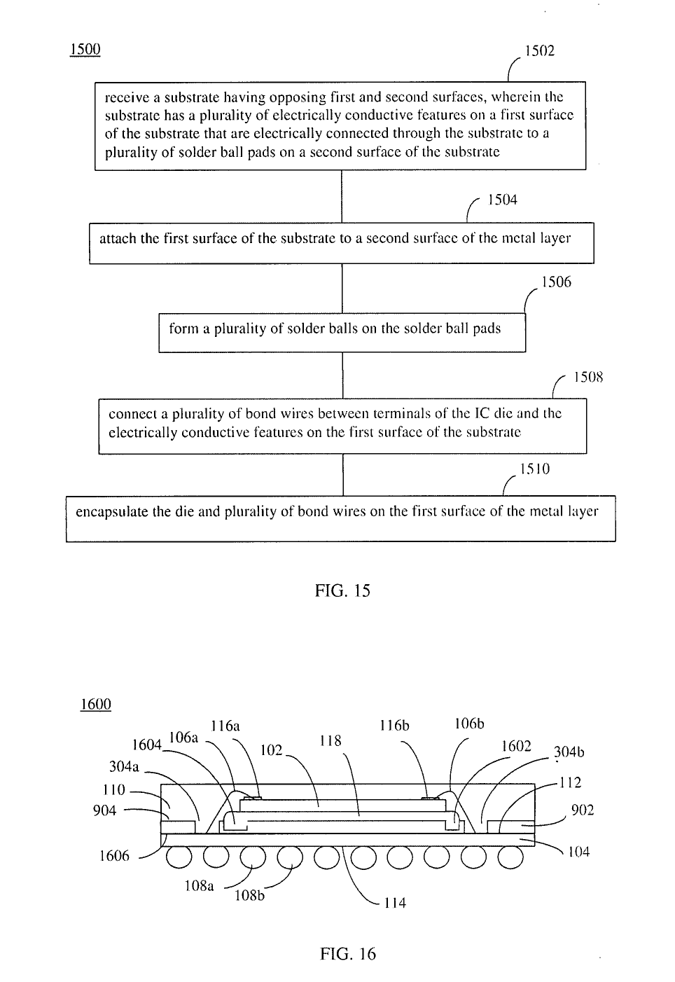

For instance, in an embodiment, flowchart 1000 may include the additional assembly steps shown in FIG. 15 to form a die-up BGA package. FIG. 16 shows a BGA package 1600 that may be assembled in this manner, according to an example embodiment of the present invention. Package 1600 is similar to package 300 of FIG. 3, with the inclusion of metal layer 902 rather than metal layer 302. Other structural and operational embodiments will be apparent to persons skilled in the relevant art(s) based on the following discussion regarding FIG. 15.

In FIG. 16, die 102 may be attached to layer 902 according to flowchart 1000, prior to or after steps shown in FIG. 15. In step 1502 of FIG. 15, a substrate having opposing first and second surfaces is received, wherein the substrate has a plurality of electrically conductive features on a first surface of the substrate that are electrically connected through the substrate to a plurality of solder ball pads on a second surface of the substrate. For example, substrate 104 shown in FIG. 16, and further described above with regard to FIG. 1, may be received.

In step 1504, the first surface of the substrate is attached to a second surface of the metal layer. For example, first surface 112 of substrate 104 may be coupled to a second surface 1606 of metal layer 902, as shown in FIG. 16. Substrate 104 and metal layer 902 may be attached in any manner, including by lamination, by an adhesive material, etc. As further shown in FIG. 16, metal layer 902 includes first and second recessed regions 1602 and 1604, adjacent to opposite ends of a die-attach region for die 102. Recessed region 1604 extends underneath die 102. First and second recessed regions 1602 and 1604 receive excess adhesive material 118 when die 102 is mounted to layer 902, to prevent the excess adhesive material 118 from substantially covering sides of die 102.

In step 1506, a plurality of solder balls is formed on the solder ball pads. For example, as shown in FIG. 16, solder balls 108 are coupled to solder ball pads (not shown in FIG. 16) on second surface 114 of substrate 104.

In step 1508, a plurality of bond wires is connected between terminals of the IC die and the electrically conductive features on the first surface of the substrate. For example, as shown in FIG. 16, bond wires 106 are connected between terminals 116 of die 102 and electrically conductive features (not shown in FIG. 16) on first surface 112 of substrate 104.

In step 1510, the die and plurality of bond wires are encapsulated on the first surface of the metal layer. For example, as shown in FIG. 16, encapsulating material 110 encapsulates die 102 and bond wires 106 on layer 902. Encapsulating material 110 may be applied in any manner, including by injecting into a mold placed over package 1600, according to a saw singulation technique, or by other technique.

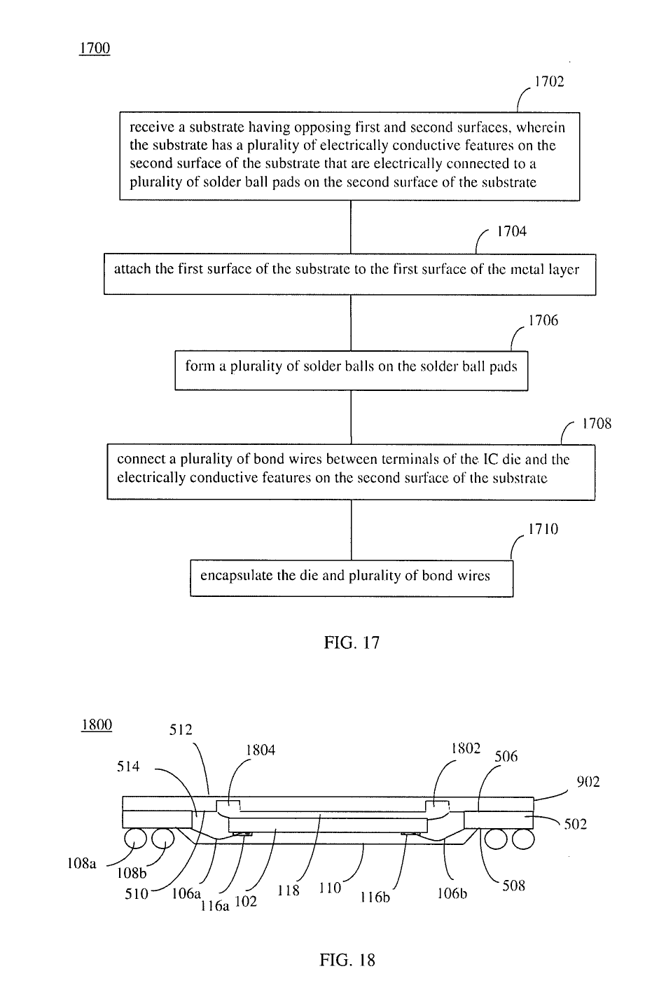

In another embodiment, flowchart 1000 may include the additional assembly steps shown in FIG. 17 to form a die-down BGA package. FIG. 18 shows a BGA package 1800 that may be assembled in this manner, according to an example embodiment of the present invention. Package 1800 is similar to package 500 of FIG. 5, with the inclusion of metal layer 902 rather than metal layer 504. Other structural and operational embodiments will be apparent to persons skilled in the relevant art(s) based on the discussion regarding the process shown in FIG. 17. FIG. 17 is described as follows.

In FIG. 18, die 102 may be attached to layer 902 according to flowchart 1000, prior to or after steps shown in FIG. 17. In step 1702, a substrate having opposing first and second surfaces is received, wherein the substrate has a plurality of electrically conductive features on the second surface of the substrate that are electrically connected to a plurality of solder ball pads on the second surface of the substrate. For example, substrate 502 shown in FIG. 18, and further described above, may be received.

In step 1704, the first surface of the substrate is attached to the first surface of the metal layer. For example, first surface 506 of substrate 502 may be coupled to first surface 510 of metal layer 902, as shown in FIG. 18. Substrate 502 and metal layer 902 may be attached in any manner, including by lamination, by an adhesive material, etc. As further shown in FIG. 18, metal layer 902 includes first and second recessed regions 1802 and 1804, adjacent to opposite ends of a die-attach region for die 102. Recessed region 1804 extends underneath die 102. First and second recessed regions 1802 and 1804 receive excess adhesive material 118 when die 102 is mounted to layer 902, to prevent the excess adhesive material 118 from substantially covering sides of die 102.

In step 1706, a plurality of solder balls is formed on the solder ball pads. For example, as shown in FIG. 18, solder balls 108 are coupled to solder ball pads (not shown in FIG. 18) on second surface 508 of substrate 502.

In step 1708, a plurality of bond wires is connected between terminals of the IC die and the electrically conductive features on the second surface of the substrate. For example, as shown in FIG. 18, bond wires 106 are connected between terminals 116 of die 102 and electrically conductive features (not shown in FIG. 18) on second surface 508 of substrate 502.

In step 1710, the die and plurality of bond wires are encapsulated. For example, as shown in FIG. 18, encapsulating material 110 encapsulates die 102 and bond wires 106 in central opening 514 of substrate 502. Encapsulating material 110 may be applied in any manner, including by injecting into a mold placed over package 1800, according to a saw singulation technique, or by other technique.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. An integrated circuit package, comprising:
a metal layer having a first surface that has a die-attach region, wherein the metal layer further has a recessed region formed in the first surface of the metal layer adjacent to the die-attach region;
an integrated circuit die having opposing first and second surfaces and a plurality of side surfaces that are substantially perpendicular to the first and second surfaces of the die; and
an adhesive material that attaches the first surface of the die to the die-attach region and at least partially fills the recessed region, wherein the plurality of side surfaces of the die are substantially uncovered by the adhesive material.

2. The package of claim 1, wherein the recessed region overlaps the die-attach region of the first surface of the metal layer.

3. The package of claim 1, wherein the recessed region is formed in a portion of the first surface of the metal layer that is outside of the die-attach region of the first surface of the metal layer.

4. The package of claim 1, wherein the metal layer is a substantially rectangular piece of metal.

5. The package of claim 4, wherein the metal is copper.

6. The package of claim 1, wherein the metal layer further comprises at least one additional recessed region formed in the first surface of the metal layer, wherein the adhesive material at least partially fills the at least one additional recessed region.

7. The package of claim 1, wherein the recessed region is rectangular.

8. The package of claim 1, wherein the recessed region has a depth that less than or equal to (≦) a half of a thickness of the metal layer.

9. The package of claim 1, further comprising:
a substrate having opposing first and second surfaces, wherein the substrate has a plurality of electrically conductive features on a first surface of the substrate that are electrically connected through the substrate to a plurality of solder ball pads on a second surface of the substrate, wherein the first surface of the substrate is attached to a second surface of the metal layer;
a plurality of solder balls coupled to the solder ball pads;
a plurality of bond wires coupled between terminals of the IC die and the electrically conductive features of the first surface of the substrate; and
an encapsulating material that covers the die and plurality of bond wires on the first surface of the metal layer.

10. The package of claim 1, further comprising:
a substrate having opposing first and second surfaces, wherein the substrate has a plurality of electrically conductive features on the second surface of the substrate that are electrically connected to a plurality of solder ball pads on the second surface of the substrate, wherein the first surface of the substrate is attached to the first surface of the metal layer;
a plurality of solder balls coupled to the solder ball pads;
a plurality of bond wires coupled between terminals of the IC die and the electrically conductive features on the second surface of the substrate; and
an encapsulating material that covers the die and plurality of bond wires.

11. A method for forming an integrated circuit package, comprising:
applying an adhesive material to a die-attach region of a first surface of a metal layer;
applying an integrated circuit die to the adhesive material, thereby causing a portion of the adhesive material to flow from between the die and first surface of the metal layer into a recessed region in the first surface of the metal layer such that a plurality of side surfaces of the die remain substantially uncovered by the adhesive material; and
curing the adhesive material to attach the die to the die-attach region.

12. The method of claim 11, further comprising:
forming the recessed region in the first surface of the metal layer.

13. The method of claim 12, wherein said forming comprises:
forming the recessed region to overlap the die-attach region of the first surface of the metal layer.

14. The method of claim 12, wherein said forming comprises:
forming the recessed region in a portion of the first surface of the metal layer that is outside of the die-attach region of the first surface of the metal layer.

15. The method of claim 12, wherein said forming comprises:
receiving a rectangular piece of metal; and
forming the recessed region in the rectangular piece of metal.

16. The method of claim 12, further comprising:
forming at least one additional recessed region in the first surface of the metal layer, wherein the adhesive material flows into the at least one additional recessed region from between the die and first surface of the metal layer during said step of applying an integrated circuit die to the adhesive material.

17. The method of claim 12, wherein said forming comprises:
forming the recessed region to have a rectangular shape.

18. The method of claim 12, wherein said forming comprises:
forming the recessed region to have a depth that less than or equal to (≦) a half of a thickness of the metal layer.

19. The method of claim 11, further comprising:
receiving a substrate having opposing first and second surfaces, wherein the substrate has a plurality of electrically conductive features on a first surface of the substrate that are electrically connected through the substrate to a plurality of solder ball pads on a second surface of the substrate;
attaching the first surface of the substrate to a second surface of the metal layer;
forming a plurality of solder balls on the solder ball pads;
connecting a plurality of bond wires between terminals of the IC die and the electrically conductive features on the first surface of the substrate; and
encapsulating the die and plurality of bond wires on the first surface of the metal layer.

20. The method of claim 11, further comprising:
receiving a substrate having opposing first and second surfaces, wherein the substrate has a plurality of electrically conductive features on the second surface of the substrate that are electrically connected to a plurality of solder ball pads on the second surface of the substrate,
attaching the first surface of the substrate to the first surface of the metal layer;
forming a plurality of solder balls on the solder ball pads;
connecting a plurality of bond wires between terminals of the IC die and the electrically conductive features on the second surface of the substrate; and
encapsulating the die and plurality of bond wires.

21. An integrated circuit package assembled in accordance with the method of claim 11.

22. A metal layer for an integrated circuit package, comprising:
a die-attach region on a first surface of the metal layer;
a recessed region in the first surface of the metal layer adjacent to the die-attach region;
wherein the recessed region is configured such that an excess portion of an adhesive material on the die-attach region flows into the recessed region when an integrated circuit die is applied to the die-attach region so that a side surface of the die remains substantially uncovered by the adhesive material.
